(19) United States
(12) Patent Application Publication
(10) Pub. No.: US 2026/0271207 A1
(43) Pub. Date: Sep. 10, 2026

(54) SEMICONDUCTOR DEVICE, POWER CONVERSION DEVICE AND MOVING BODY

(71) Applicant: Mitsubishi Electric Corporation, Tokyo (JP)

(72) Inventor: Ryutaro DATE, Tokyo (JP)

(73) Assignee: Mitsubishi Electric Corporation, Tokyo (JP)

(21) Appl. No.: 18/873,251

(22) PCT Filed: Oct. 7, 2022
(86) PCT No.: PCT/JP2022/037643

§ 371 Date: Dec. 9, 2024

(51) Int. Cl. H05K 5/13; H05K 1/181

(52) U.S. Cl. CPC H05K 5/13; H05K 1/181

(57) ABSTRACT

A semiconductor device according to the disclosure includes a base plate, a semiconductor chip provided in a region above the base plate, a case provided on the base plate, enclosing the semiconductor chip, including an outer surface and an inner surface on an opposite side of the outer surface, and including a recess formed on the outer surface, a nut pressed into the recess of the case and having a screw hole formed to extend in a vertical direction, and a screw inserted into the nut from below the base plate.

### FIELD

The present disclosure relates to a semiconductor device, a power conversion device and a moving body.

### BACKGROUND

PTL 1 discloses a semiconductor device including a resin case including a screw hole, an insulating substrate on which a semiconductor chip is mounted, and a heatsink which includes a heatsink through-hole and on which the insulating substrate is mounted. A metal tapping screw passes through the heatsink through-hole and the screw hole and engages the resin case with the heatsink. A void in the screw hole formed between the resin case and the metal tapping screw is filled with a high withstand voltage resin.

### CITATION LIST

### Patent Literature

[PTL 1] JP 2006-32392 A

### SUMMARY

### Technical Problem

As reduction in size and increase in density of a semiconductor device proceed, a distance between a screw and an insulating substrate becomes shorter. It is therefore necessary to improve partial discharge withstand capability and breakdown withstand capability. For example, if a case and a heatsink, or the like, are screw-fastened with a tapping screw, a void is likely to be generated around the screw. There is a possibility that the partial discharge withstand capability may degrade due to this void.

In contrast, in PTL 1, the discharge withstand capability is improved by filling the void between the case and the screw with a resin. However, manufacturing processes increase due to filling of the void with the resin, and there is a possibility that workability may degrade.

The present disclosure is directed to providing a semiconductor device, a power conversion device and a moving body that can improve discharge withstand capability.

### Solution to Problem

A semiconductor device according to the first disclosure includes a base plate; a semiconductor chip provided in a region above the base plate; a case provided on the base plate, enclosing the semiconductor chip, including an outer surface and an inner surface on an opposite side of the outer surface, and including a recess formed on the outer surface; a nut pressed into the recess of the case and having a screw hole formed to extend in a vertical direction; and a screw inserted into the nut from below the base plate.

A semiconductor device according to the second disclosure includes a base plate; a semiconductor chip provided in a region above the base plate; a case provided on the base plate and enclosing the semiconductor chip; a nut provided on the case in a region enclosed by the case, the nut being a cap nut that is open downward; and a screw inserted into the nut from below the base plate.

### Advantageous Effects of Invention

In the semiconductor devices according to the first and the second disclosures, it is possible to prevent a void from being formed between the screw and a member on the base plate that becomes a high voltage. It is therefore possible to improve discharge withstand capability.

### Brief Description of Drawings

FIG. 1 is a cross-sectional view of a semiconductor device according to a first embodiment.

FIG. 2 is a plan view of the semiconductor device according to the first embodiment.

FIG. 3 is a cross-sectional view illustrating a state where a case and a base plate are fastened with a screw in the semiconductor device according to the first embodiment.

FIG. 4 is a view for explaining an insulating substrate according to the first embodiment.

FIG. 5 is a cross-sectional view of a semiconductor device according to a comparative example.

FIG. 6 is a view for explaining a gas in a case according to the comparative example.

FIG. 7 is a view for explaining the gas within the case according to the first embodiment.

FIG. 8 is a plan view of a semiconductor device according to a second embodiment.

FIG. 9 is a cross-sectional view of a semiconductor device according to a third embodiment.

FIG. 10 is a plan view of the semiconductor device according to the third embodiment.

FIG. 11 is a cross-sectional view illustrating a state where a case and the base plate are fastened with the screw in the semiconductor device according to the third embodiment.

FIG. 12 is a plan view of a semiconductor device according to a fourth embodiment.

FIG. 13 is a block diagram of a power conversion device according to a fifth embodiment.

FIG. 14 is a view for explaining a moving body according to a sixth embodiment.

### DESCRIPTION OF EMBODIMENTS

A semiconductor device and a semiconductor device, a power conversion device and a moving body according to each embodiment are described with reference to drawings. Identical or corresponding constitutional elements are given the same reference numerals, and the repeated description of such constitutional elements may be omitted.

### First Embodiment

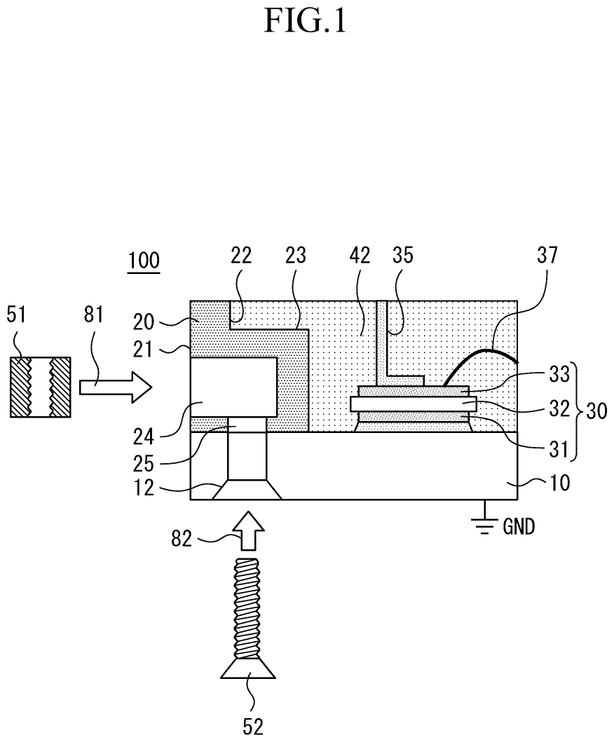

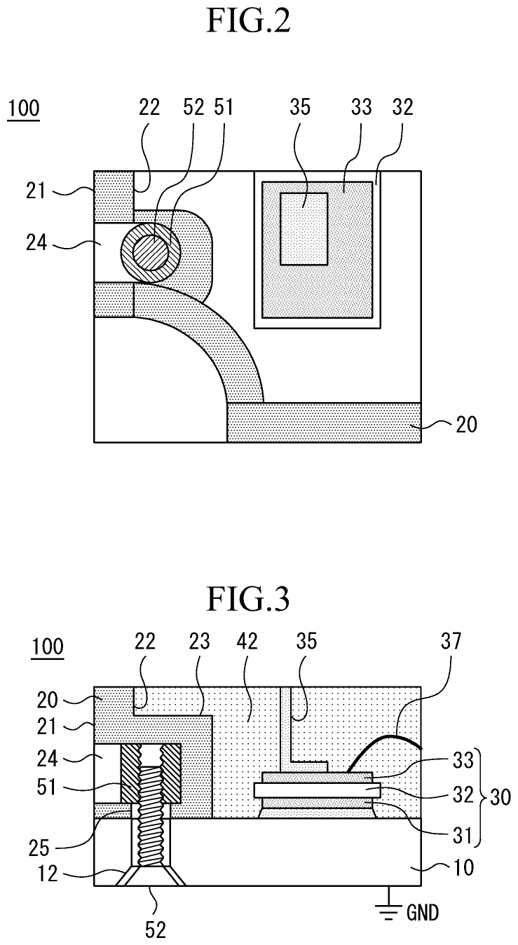

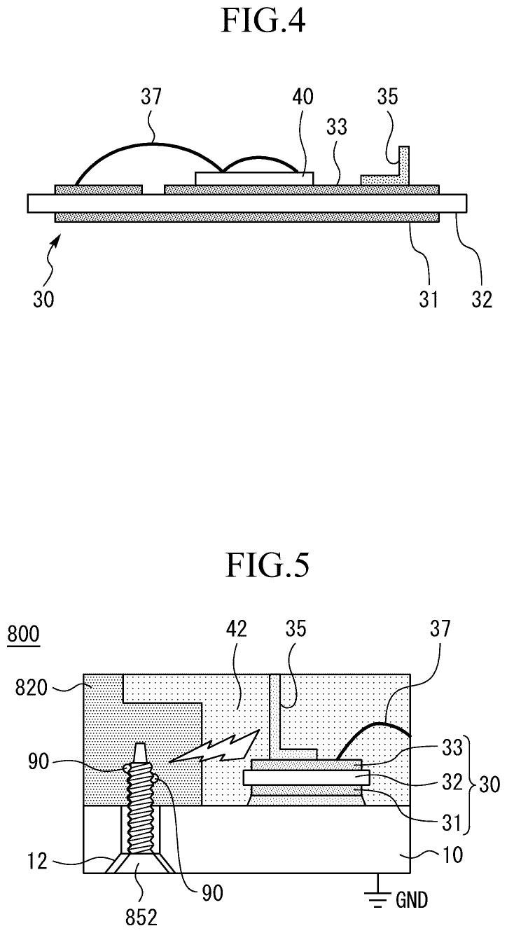

FIG. 1 is a cross-sectional view of a semiconductor device 100 according to a first embodiment. FIG. 2 is a plan view of the semiconductor device 100 according to the first embodiment. FIG. 3 is a cross-sectional view illustrating a state where a case 20 and a base plate 10 are fastened with a screw 52 in the semiconductor device 100 according to the first embodiment. FIG. 4 is a view for explaining an insulating substrate 30 according to the first embodiment. In the semiconductor device 100, the insulating substrate 30 is mounted on the base plate 10.

As illustrated in FIG. 4, the insulating substrate 30 includes a conductor layer 31, an insulating layer 32 on the conductor layer 31, and a metal pattern 33 on the insulating layer 32. The insulating layer 32 is formed with, for example, ceramics or a resin. A semiconductor chip 40 is provided on the metal pattern 33. The semiconductor chip 40 is, for example, an insulated gate bipolar transistor (IGBT) chip or a diode (Di) chip. In this manner, the semiconductor chip 40 is provided in a region above the base plate 10. Further, a metal terminal 35 that is an electrode, a metal wiring 37 that is a wire, or the like, are provided on the metal pattern 33. Note that in FIGS. 1 to 3, only part of the insulating substrate 30 is illustrated for convenience sake.

The case 20 enclosing the semiconductor chip is provided on the base plate 10. For convenience sake, only part of the case 20 is illustrated in FIGS. 1 to 3. The case 20 includes an outer surface 21 and an inner surface 22 on an opposite side of the outer surface 21. A recess 24 is formed on the outer surface 21. The case 20 includes a pedestal portion 23 projecting inward of a region enclosed by the case 20. The recess 24 is formed in the pedestal portion 23. The region enclosed by the case 20 is filled with a sealing material 42. An electrode (not illustrated) is provided in the case 20. Further, a lid (not illustrated) is provided on the case 20. The semiconductor chip 40, the metal pattern 33, the metal terminal 35 and the electrode of the case 20 are electrically connected through the metal wiring 37, ultrasonic (US) bonding, or the like.

A nut 51 is pressed into the recess 24 of the case 20. A screw hole extending in a vertical direction is formed in the nut 51. A through-hole 12 through which a screw 52 is to be inserted is formed in the base plate 10. Further, a through-hole 25 connecting the recess 24 and the through-hole 12 is formed in the case 20. The screw 52 is inserted into the nut 51 through the through-holes 12 and 25 from below the base plate 10. The screw 52 is, for example, a bolt to be screwed with the nut 51. By this means, as illustrated in FIG. 3, the case 20 and the base plate 10 are fastened. The nut 51 has, for example, a circular shape in plan view.

FIG. 5 is a cross-sectional view of a semiconductor device 800 according to a comparative example. The semiconductor device 800 according to the comparative example is different from the semiconductor device 100 of the first embodiment in that a case 820 and the base plate 10 are fastened with a tapping screw 852. In this configuration, a void 90 may be generated between the tapping screw 852 and the case 20 as a result of fastening being performed with the tapping screw 852. Partial discharge occurs by voltages being exchanged between a projecting portion such as, for example, a screw thread of the screw and the metal pattern 33, the metal terminal 35, the metal wiring 37, or the like, that becomes a high voltage. In the semiconductor device 800 according to the comparative example, the void 90 is likely to be formed on a line that connects the tapping screw 852 and the high voltage portion. Thus, there is a possibility that partial discharge withstand capability may degrade due to the void 90.

In contrast, in the present embodiment, the base plate 10 and the case 20 can be fastened without the case 20 being scraped by the tapping screw 852. Thus, generation of the void 90 between the screw 52 and the case 20 can be prevented, and occurrence of partial discharge can be prevented. It is therefore possible to improve discharge withstand capability. Note that a void above the screw 52 and a void between the screw 52 and the case 20 in the through-hole 25 are not located on a line that connects the screw 52 and the high voltage portion with a shortest path. Thus, degradation of partial discharge withstand capability is less likely to be led.

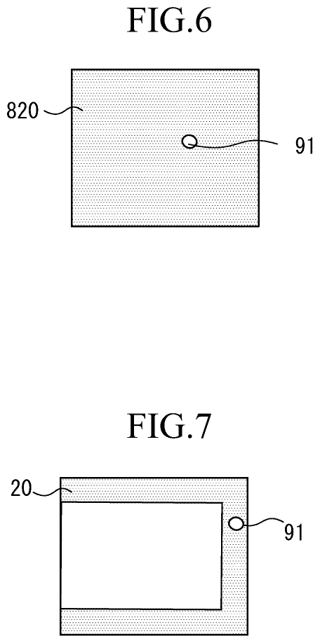

FIG. 6 is a view for explaining a gas 91 in a case 820 according to the comparative example. In the case formed with a resin, an amount of a gas generated from a molding resin increases as a volume of a resin portion is larger. The recess 24 is not formed in the case 820 according to the comparative example. Thus, a volume of the case 820 is large, and a void is likely to be generated by the gas 91. Further, there is no recess 24 in the case 820, and thus, a block-shaped thick portion is formed. In the block-shaped portion, a distance from inside of the case to the surface is long. Thus, the gas 91 generated upon formation is less likely to go out, and a void is more likely to be generated. Thus, in the semiconductor device 800 according to the comparative example, a void is likely to be formed on a line that connects the tapping screw 852 and the high voltage portion. Also by this void, there is a possibility that partial discharge withstand capability may degrade.

FIG. 7 is a view for explaining the gas 91 within the case 20 according to the first embodiment. In the present embodiment, the recess 24 is formed in the case 20. As a result of the recess 24 being formed, a volume of the case 20 decreases. It is therefore possible to prevent generation of a void when the case 20 is formed with a resin. Further, in the present embodiment, as a result of the recess 24 being formed in the pedestal portion 23, the pedestal portion 23 can be formed with a thin plate-like portion. In the plate-like portion, a distance from inside of the case 20 to the surface is short. Thus, the gas 91 generated upon formation is likely to go out, and a void is less likely to be generated. In this manner, in the present embodiment, it is possible to prevent a void from being formed between the screw 52 and the high voltage portion. It is therefore possible to improve discharge withstand capability.

Further, in the present embodiment, it is not necessary to fill the void between the case and the screw with a resin to improve discharge withstand capability. It is therefore possible to prevent increase of manufacturing processes and improve workability.

The nut 51 is preferably formed with an insulating body such as a resin, and the screw 52 is preferably formed with a metal. In this event, the screw 52 is electrically connected to the base plate 10 that is a GND and has a GND potential. By combining the screw 52 that has a GND potential and the nut 51 that is non-conductor for the high voltage portion, it is possible to effectively prevent partial discharge. Both of the nut 51 and the screw 52 may be a metal, or both may be an insulating body such as a resin. Further, the nut 51 may be a metal, and the screw 52 may be a resin.

As a modification of the present embodiment, the semiconductor chip 40 may be a metal-oxide-semiconductor field-effect transistor (MOSFET) chip. Further, a plurality of semiconductor chips 40 may be provided in the case 20. The plurality of semiconductor chips 40 may include a plurality of types of semiconductor chips. Also in this case, effects similar to the effects of the present embodiment can be provided.

The semiconductor chip 40 may be made with a wide bandgap semiconductor. The wide bandgap semiconductor is, for example, silicon carbide, gallium nitride-based material or diamond. By using a wide bandgap semiconductor as the semiconductor chip 40, it is possible to save energy of the semiconductor device 100. Further, according to the present embodiment, in the semiconductor device 100 in which the semiconductor chip 40 made with a wide bandgap semiconductor is provided, even in a case where a high current flows, it is possible to improve discharge withstand capability and implement stable operation.

These modifications can be applied, as appropriate, to semiconductor devices, power conversion devices and moving bodies according to the following embodiments. Note that the semiconductor devices, the power conversion devices and the moving bodies devices according to the following embodiments are similar to those of the first embodiment in many respects, and thus differences between the semiconductor devices, the power conversion devices and the moving bodies according to the following embodiments and those of the first embodiment will be mainly described below.

### Second Embodiment

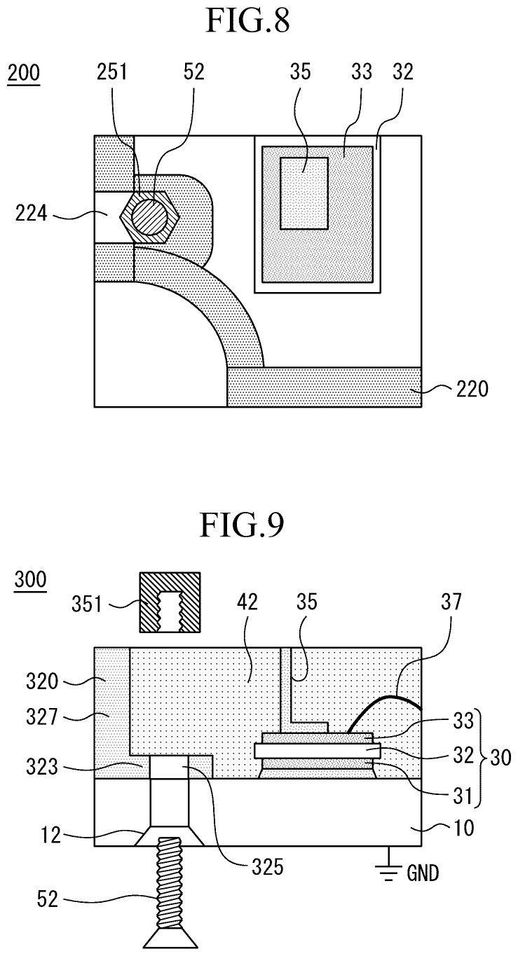

FIG. 8 is a plan view of a semiconductor device 200 according to a second embodiment. In the present embodiment, shapes of a nut 251 and a recess 224 of the case 220 are different from the shapes in the first embodiment. Other configurations are similar to the configurations of the first embodiment. The nut 251 has a polygonal shape in plan view. The nut 251 has, for example, a hexagonal or quadrangular shape in plan view. The recess 224 of the case 220 has a shape in accordance with the nut 251. In other words, a side surface of the case 220 in the recess 224 is configured to tightly adhere to the nut 251.

In the present embodiment, it is possible to prevent co-rotation of the nut 251. This makes it possible to reliably generate fastening torque required for fastening the case 220 and the base plate 10.

### Third Embodiment

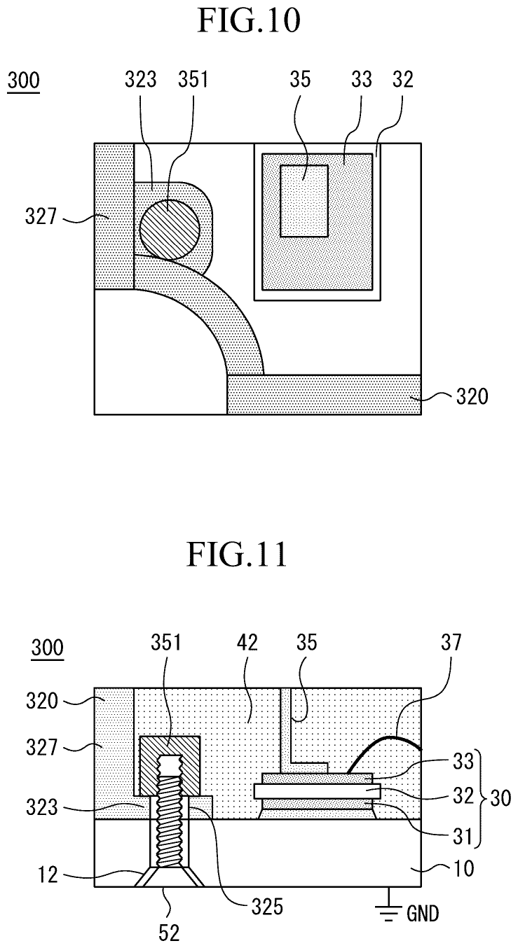

FIG. 9 is a cross-sectional view of a semiconductor device 300 according to a third embodiment. FIG. 10 is a plan view of the semiconductor device 300 according to the third embodiment. FIG. 11 is a cross-sectional view illustrating a state where a case 320 and the base plate 10 are fastened with the screw 52 in the semiconductor device 300 according to the third embodiment. In the present embodiment, configurations of the case 320 and a nut 351 are different from the configurations of the first embodiment. Other configurations are similar to the configurations of the first embodiment.

The case 320 enclosing the semiconductor chip 40 is provided on the base plate 10. For convenience sake, FIGS. 9 to 11 illustrate only part of the case 320. The case 320 includes a side wall portion 327 extending upward from an upper surface of the base plate 10 and a pedestal portion 323 extending along the upper surface of the base plate 10. The nut 351 is provided on the case 320 in a region enclosed by the case 320. Specifically, the nut 351 is provided on the pedestal portion 323. The nut 351 is a cap nut that is open downward.

The through-hole 25 is formed in the case 320 so as to connect to the through-hole 12. The screw 52 is inserted into the nut 351 through the through-holes 12 and 25 from below the base plate 10. The screw 52 is, for example, a bolt to be screwed with the nut 351. By this means, as illustrated in FIG. 11, the case 320 and the base plate 10 are fastened. The nut 351 has, for example, a circular shape in plan view.

Also in the present embodiment, the base plate 10 and the case 320 can be fastened without the case 320 being scraped by the tapping screw 852. Thus, generation of the void 90 between the screw 52 and the case 320 can be prevented, and occurrence of partial discharge can be prevented. It is therefore possible to improve discharge withstand capability.

Further, in the case 320 of the present embodiment, the block-shaped thick portion for allowing insertion of the tapping screw 852 like the case 820 according to the comparative example is not provided. It is therefore possible to reduce a volume of the case 320 and prevent generation of a void when the case 320 is formed with a resin. Further, in the present embodiment, the pedestal portion 323 of the case 320 can be formed with a thin plate-like portion. Thus, the gas 91 generated when the case 320 is formed is less likely to go out, so that it is possible to prevent generation of a void.

Further, by using a cap nut as the nut 351, it is possible to prevent the sealing material 42 from exuding from between the nut and the screw 52. In the present embodiment, it is possible to cause the sealing material 42 to tightly adhere to the cap nut without space therebetween.

### Fourth Embodiment

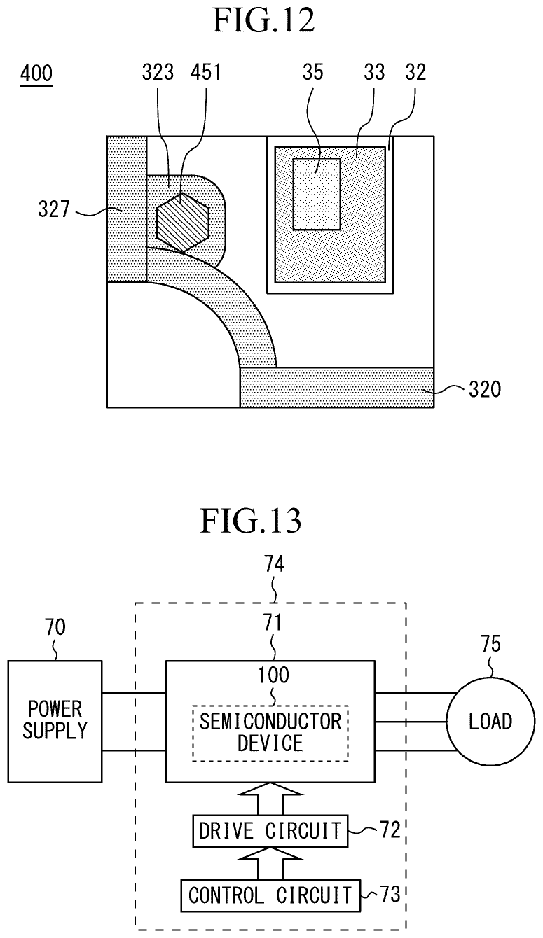

FIG. 12 is a plan view of a semiconductor device 400 according to a fourth embodiment. In the present embodiment, a shape of a nut 451 is different from the shape of the nut 351 in the third embodiment. Other configurations are similar to the configurations of the first embodiment. The nut 451 has a polygonal shape in plan view. The nut 451 has, for example, a hexagonal or quadrangular shape in plan view.

In the present embodiment, for example, as a result of a side surface or a corner of the nut 451 coming into contact with a side surface of the case 320, co-rotation of the nut 451 can be prevented. This makes it possible to reliably generate fastening torque required for fastening the case 320 and the base plate 10.

### Fifth Embodiment

FIG. 13 is a block diagram of a power conversion device 74 according to a fifth embodiment. The power conversion device 74 is, for example, a three-phase inverter. The power conversion device 74, which is connected between a power supply 70 and a load 75, converts power supplied from the power supply 70 and supplies the converted power to the load 75. The power conversion device 74 includes a main conversion circuit 71 that converts power and outputs the converted power, a drive circuit 72 that outputs a drive signal for driving a switching device of the main conversion circuit 71, and a control circuit 73 that outputs a control signal for controlling the drive circuit 72 to the drive circuit 72.

In the power conversion device 74 according to the present embodiment, one of the semiconductor devices of the first to the fourth embodiments is mounted as the switching device of the main conversion circuit 71. This can improve discharge withstand capability of the power conversion device 74.

The power conversion device 74 may be a two-level, three-level or multi-level power conversion device. The present embodiment can be also applied to a single-phase inverter, a DC/DC converter and an AC/DC converter.

The load 75 is, for example, an electric motor. The present disclosure is not limited to this, and the power conversion device 74 can be also used as, for example, a power supply device of electric discharge machine, laser machine, an induction heating cooker and a non-contact power supply system. Further, the power conversion device 74 can be also used as a power conditioner of a photovoltaic system, an electricity storage system, or the like.

### Sixth Embodiment

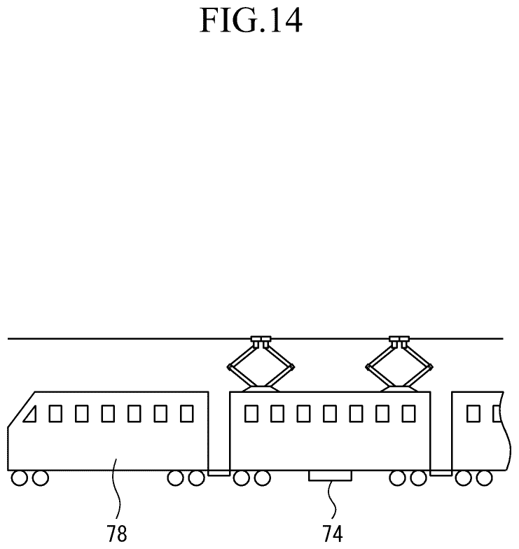

FIG. 14 is a view for explaining a moving body 78 according to a sixth embodiment. In the moving body 78, the power conversion device 74 including one of the semiconductor devices of the first to the fourth embodiments is mounted. The moving body 78 is, for example, a train. In the present embodiment, by improving discharge withstand capability of the power conversion device 74, it is possible to lengthen the life of the moving body 78.

Note that the technical features described in the above embodiments may be combined as appropriate.

### REFERENCE SIGNS LIST

10 base plate, 12 through-hole, 20 case, 21 outer surface, 22 inner surface, 23 pedestal portion, 24 recess, 25 through-hole, 30 substrate, 31 conductor layer, 32 insulating layer, 33 metal pattern, 35 metal terminal, 37 metal wiring, 40 semiconductor chip, 42 sealing material, 51 nut, 52 screw, 70 power supply, 71 main conversion circuit, 72 drive circuit, 73 control circuit, 74 power conversion device, 75 load, 78 moving body, 90 void, 91 gas, 100 semiconductor device, 200 semiconductor device, 220 case, 224 recess, 251 nut, 300 semiconductor device, 320 case 323 pedestal portion, 327 side wall portion, 351 nut, 400 semiconductor device, 451 nut, 800 semiconductor device, 820 case, 852 tapping screw

1. A semiconductor device comprising:
a base plate;
a semiconductor chip provided in a region above the base plate;
a case provided on the base plate, enclosing the semiconductor chip, including an outer surface and an inner surface on an opposite side of the outer surface, and including a recess formed on the outer surface;
a nut pressed into the recess of the case and having a screw hole formed to extend in a vertical direction; and
a screw inserted into the nut from below the base plate.

2. A semiconductor device comprising:
a base plate;
a semiconductor chip provided in a region above the base plate;
a case provided on the base plate and enclosing the semiconductor chip;
a nut provided on the case in a region enclosed by the case, the nut being a cap nut that is open downward; and
a screw inserted into the nut from below the base plate.

3. The semiconductor device according to claim 1-92, wherein the nut is formed with an insulating body, and the screw is formed with a metal.

4. The semiconductor device according to claim 1, wherein the nut has a polygonal shape in plan view.

5. The semiconductor device according to claim 1, wherein the semiconductor chip is made with a wide bandgap semiconductor.

6. The semiconductor device according to claim 5, wherein the wide bandgap semiconductor is silicon carbide, gallium-nitride-based material or diamond.

7. A power conversion device on which the semiconductor device according to claim 1 is mounted.

8. A moving body on which the semiconductor device according to claim 1 is mounted.

9. The semiconductor device according to claim 2, wherein the nut is formed with an insulating body, and the screw is formed with a metal.

10. The semiconductor device according to claim 2, wherein the nut has a polygonal shape in plan view.

11. The semiconductor device according to claim 2, wherein the semiconductor chip is made with a wide bandgap semiconductor.

12. The semiconductor device according to claim 11, wherein the wide bandgap semiconductor is silicon carbide, gallium-nitride-based material or diamond.

13. A power conversion device on which the semiconductor device according to claim 2 is mounted.

14. A moving body on which the semiconductor device according to claim 2 is mounted.
